(19) United States
(12) Patent Application Publication
(10) Pub. No.: US 2025/0286541 A1
(43) Pub. Date: Sep. 11, 2025

(54) PHASE FREQUENCY DETECTOR AND ITS METHOD OF OPERATION

(71) Applicant: INDIAN INSTITUTE OF TECHNOLOGY ROPAR, Punjab (IN)

(72) Inventors: Mahendra SAKARE, Punjab (IN); Mayank Kumar SINGH, Punjab (IN); Hirensh MEHRA, Punjab (IN); Rajasekhar NAGULAPALLI, Punjab (IN)

(21) Appl. No.: 18/747,995

(22) Filed: Jun. 19, 2024

(30) Foreign Application Priority Data
Mar. 8, 2024 (IN) 202411016895

(51) Int. Cl. H03K 3/037; H03K 3/012; H03K 19/096

(52) U.S. Cl. CPC H03K 3/037; H03K 3/012; H03K 19/0963

(57) ABSTRACT

A circuit for an edge-based Phase Frequency Detector (PFD) (200) comprising two edge detectors (103), two SR latches (104), one NAND gate (106), and one NOR gate (107). A reference (Ref) (101) and feedback signals (Fb) (102) are provided to the two edge detector (103) which generates a pulse of active low logic. The output of the edge detector (103) is provided to the two SR latches (104), which provide output signals of the phase frequency detectors. The output of two SR latch (104) is buffered though two invertors (201) and additionally connected to a pair of cross-coupled inverters (202) to generate complementary up (UP and UPb) and down (DN and DNb) signals (105). Phase Frequency Detector (PFD) circuit (200) minimize the number of gates, reducing noise and Random Jitter (RJ), enhance dead zone performance and also reduce the duty cycle of the reference (Ref) (101) and feedback (Fb) signal (102) to a minimal 10%.

### CROSS-REFERENCE TO RELATED APPLICATIONS AND PRIORITY

The present application claims priority from any the Indian Patent Application number 202411016895 filed on 8 Mar. 2024.

### TECHNICAL FIELD

The present subject matter described herein, in general, relates to a phase frequency detector (PFD). Particularly, the present subject matter relates to an edge generation-based phase frequency detector for frequency synthesis system.

### BACKGROUND OF THE INVENTION

In conventional wireline/wireless receivers, maintaining a stable and low-jitter clock for precise data sampling is essential. Typically operating at frequencies ranging from 1 to 12.5 GHz, these receivers face the challenge of deriving such high frequencies from a reference signal within the 0.01-156 MHz range. A synthesizer generates the required high frequency by using existing Integer-N Phase-Locked Loop (PLL).

Traditional phase locked loop (PLL) include the Phase Frequency Detector (PFD), Charge Pump (CP), Loop Filter, Voltage-Controlled Oscillator (VCO), and frequency divider. The PFD produces a phase error signal at its output, and the CP generates current pulses whose width correlates with the phase error. As these current pulses exhibit a broader bandwidth, a loop filter is incorporated to filter out high-frequency content. This filtered signal is then provided to the VCO to attain the desired frequency, creating a negative feedback system. The outcome is an output clock with a frequency equal to the product of the reference frequency and the divider value.

The conventional Phase Frequency Detector (PFD) has several drawbacks like it relies on 4 latches (2 flip-flops) and one NAND gate (106), resulting in an average of 8 to 9 basic logic gates in the critical signal path (through 4 latches). This configuration introduces significant jitter and power consumption. The extended delay in the reset path limits the PFD's high-frequency performance, limiting its effectiveness to 350 MHz in 28 nm CMOS technology. Typically, complementary signals for up/dn are not readily available, necessitating additional components such as XOR gates or inverters for their generation. Any mismatch in the overlap time of these signals may lead to undesirable reference spurs. Several NAND gates (106) in the signal path contribute to high Deterministic Jitter (DJ) and poor Power Supply Rejection Ratio (PSRR).

Hence to overcome the aforesaid drawbacks an efficient low-noise PFD circuit is required to enhance the overall performance of this intricate clock generation system.

### OBJECTS OF THE INVENTION

Main object of the present disclosure is to provide an edge generation-based phase frequency detector (PFD) to identify the clock errors of reference clock and feedback clock and generates an error signal proportional to the input phase error.

Another object of the present disclosure is to provide the edge generation-based phase frequency detector (PFD) to minimize the number of gates, as well as to reduce noise and Random Jitter (RJ).

Yet another object of the present disclosure is to provide the edge generation-based phase frequency detector (PFD) to reduce the duty cycle of the reference (Ref) and feedback (Fb) clocks to a minimal 10%.

### SUMMARY OF THE INVENTION

Before the present system is described, it is to be understood that this application is not limited to the particular machine, device, or system, as there can be multiple possible embodiments that are not expressly illustrated in the present disclosures. It is also to be understood that the terminology used in the description is for the purpose of describing the particular versions or embodiments only, and is not intended to limit the scope of the present application. This summary is provided to introduce aspects related to an edge generation-based phase frequency detector (PFD), and the aspects are further elaborated below in the detailed description. This summary is not intended to identify essential features of the proposed subject matter nor is it intended for use in determining or limiting the scope of the proposed subject matter.

In an embodiment the present invention discloses a phase frequency detector (PFD), comprising: a first edge detection circuit (103) configured to receive a reference clock signal (101) and generate a first output signal indicative of an edge of the reference clock signal; a second edge detection circuit (103) configured to receive a feedback clock signal and generate a second output signal indicative of an edge of the feedback clock signal; a phase detection circuit configured to receive the first and second output signals and generate a third signal indicative of a phase difference between the reference clock signal and the feedback clock signal, wherein the phase detection circuit comprises: two SR latches, each configured to receive one of the first and second output signals; a first logic gate configured to receive outputs of the two SR latches and generate a first output signal indicative of the phase difference; and a second logic gate configured to receive outputs of the two SR latches and generate a second output signal complementary to the first output signal. in each edge detection circuit comprises a NAND gate configured to receive the corresponding clock signal and a complement of the corresponding clock signal.

In an embodiment the present invention discloses, the NAND gates (106) of the edge detection circuits comprise transistors. In an embodiment, wherein the transistors are configured as NMOS transistors. In an embodiment, wherein the first and second logic gates are NAND gates.

In yet another embodiment the present invention provides a first inverter (201) configured to receive the first output signal of the phase detection circuit; and a second inverter (202) configured to receive the output of the first inverter, wherein the PFD is configured to output the first output signal of the phase detection circuit as a first up signal and the output of the second inverter as a down signal.

In yet another embodiment the present invention discloses, a reset circuit configured to reset the SR latches.

In yet another embodiment the present invention provides, the reset circuit comprises a third logic gate configured to receive the first and second output signals of the phase detection circuit and generate a reset signal.

In yet another embodiment the present invention provides the third logic gate is a NOR gate (107).

In yet another embodiment the present invention provides the edge detection circuits are configured to generate output signals with a pulse width of less than 50% of a period of the corresponding clock signal.

In yet another embodiment the present invention provides that the PFD operates at a frequency greater than 1 GHZ.

In yet another embodiment the present invention provides a method for generating up and down signals indicative of a phase difference between a reference clock signal and a feedback clock signal, the method comprising: generating first and second output signals indicative of edges of the reference clock signal and the feedback clock signal, respectively; receiving the first and second output signals in a phase detection circuit; generating a first output signal indicative of the phase difference based on the first and second output signals; and generating a second output signal complementary to the first output signal.

### BRIEF DESCRIPTION OF DRAWING

The foregoing summary, as well as the following detailed description of embodiments, is better understood when read in conjunction with the appended drawings. For the purpose of illustrating the disclosure, there is shown in the present document example constructions of the disclosure, however, the disclosure is not limited to the specific methods and device disclosed in the document and the drawing. The detailed description is described with reference to the following accompanying figures.

FIG. 1: illustrates the prior art consisting of Integer-N phase locked loop (PLL) block diagram, in accordance with an embodiment of the present subject matter.

FIG. 2: illustrates the prior art consisting of a conventional phase frequency detector (PFD) configured with D-Flip flop, in accordance with an embodiment of the present subject matter.

FIG. 3: illustrates the prior art consisting of state diagram of the conventional phase frequency detector PFD, in accordance with an embodiment of the present subject matter.

FIG. 4: illustrates the timing diagram of 3-state phase frequency detector (PFD), in accordance with an embodiment of the present subject matter.

FIG. 5: illustrates the block-level implementation of phase frequency detector (PFD), in accordance with an embodiment of the present subject matter.

FIG. 6: illustrates the transistor-level implementation of phase frequency detector (PFD), in accordance with an embodiment of the present subject matter.

FIG. 7: illustrates the graph showing a comparison of phase noise between the conventional and proposed PFD system, in accordance with an embodiment of the present subject matter.

The figures depict various embodiments of the present disclosure for purposes of illustration only. One skilled in the art will readily recognize from the following discussion that alternative embodiments of the structures illustrated herein may be employed without departing from the principles of the disclosure described herein.

### DETAILED DESCRIPTION OF THE INVENTION

Some embodiments of this disclosure, illustrating all its features, will now be discussed in detail. The words “comprising”, “having”, and “including,” and other forms thereof, are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise. Although any devices and methods similar or equivalent to those described herein can be used in the practice or testing of embodiments of the present disclosure, the exemplary, devices and methods are now described. The disclosed embodiments are merely exemplary of the disclosure, which may be embodied in various forms.

Various modifications to the embodiment will be readily apparent to those skilled in the art and the generic principles herein may be applied to other embodiments. However, one of ordinary skill in the art will readily recognize that the present disclosure is not intended to be limited to the embodiments illustrated, but is to be accorded the widest scope consistent with the principles and features described herein.

Following is a list of elements and reference numerals used to explain various embodiments of the present subject matter.

| Reference Numeral | Element Description |
|---|---|
| 100 | Block diagram of phase frequency detector (PFD) |
| 101 | Reference signal (Ref) |
| 102 | Feedback signal (Fb) |
| 103 | Edge detector |
| 104 | SR latch |
| 105 | Complementary up and down signals |
| | (Up, Upb, Dn, and Dnb) |
| 106 | NAND gate |
| 107 | NOR gate |
| 200 | Circuit diagram of phase frequency detector (PFD) |
| 201 | Inverters |
| 202 | Cross coupled inverter |

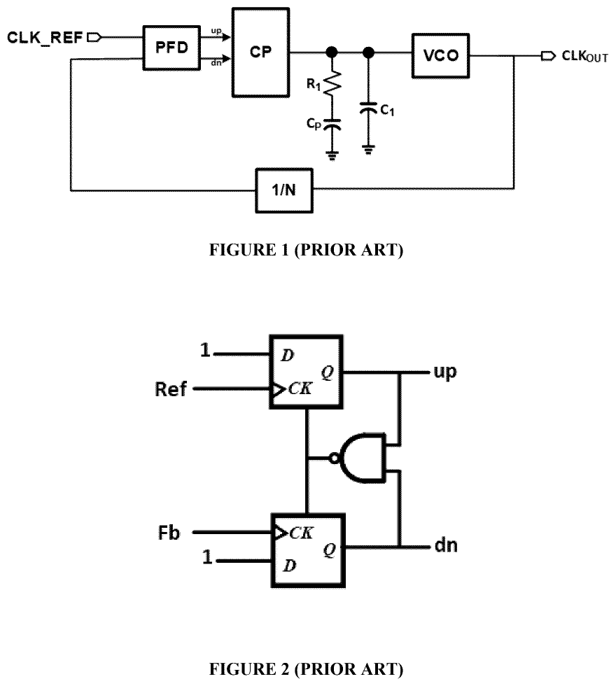

FIG. 1 illustrates a prior art showing a block diagram of an Integer-N Phase-Locked Loop (PLL). The key components of this PLL include the Phase Frequency Detector (PFD), Charge Pump (CP), Loop Filter, Voltage-Controlled Oscillator (VCO), and frequency divider. The PFD produces a phase error signal at its output, and the CP generates current pulses whose width correlates with the phase error. As these current pulses exhibit a broader bandwidth, a loop filter is incorporated to filter out high-frequency content. This filtered signal is then provided to the VCO to attain the desired frequency, creating a negative feedback system. The outcome is an output clock with a frequency equal to the product of the reference frequency and the divider value. Therefore, a low-noise PFD designed to enhance the overall performance of this intricate clock generation system.

FIG. 2 illustrates a prior art showing a block diagram of a conventional phase frequency detector (PFD). The conventional PFD comprises two D-flip-flops with data inputs tied to the supply voltage, indicating logic ‘high.’ Both flip-flops are clocked by the reference (Ref) (101) and feedback (Fb) clocks (102). The reset signal for the flip-flops is generated by a NAND gate (106), with its inputs connected to the outputs of the flip-flops. If the Ref clock leads the Fb clock, the output of the top flip-flop rises to ‘high,’ and when the Fb clock rises, the down (dn) signal also rises to ‘high.’ When both up and dn (105) are high, the NAND gate (106) resets the flip-flop outputs to ‘low.’ Consequently, the pulse width of the up signal is proportional to the phase error and vice versa.

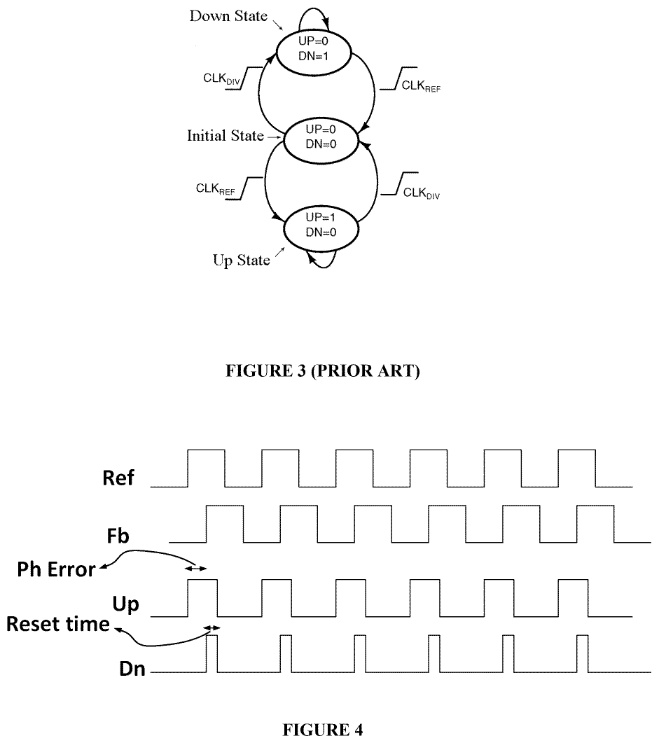

FIG. 3 illustrates a prior art showing a state diagram of the conventional PFD. This state diagram exhibits three states depending on the phase error. FIG. 3 represents how the up and dn signals transition among the states (up and dn corresponding to 00 (for initial state)/01 (for down state)/10 (for up state)). Notably, the simultaneous occurrence of up and dn signals staying at ‘11’ state is deemed unacceptable due to the potential for glitches, which may occur several times.

FIG. 4 illustrates a timing diagram of 3-state PFD containing timing information within a Phase Frequency Detector (PFD) when the reference frequency (Rf) (101) leads the feedback clock (Fb) (102). PFD generate a pulse with active low logic (brief low-time (Dn) and high for the remaining duration (Up)). The active low time depends on the inverter delay. As a standard practice, a slight delay (typically 500 ps) is often introduced in the reset path to eliminate the dead zone effectively.

Proposed edge-based Phase Frequency Detector (PFD) designed specifically for Integer-N Phase-Locked Loop (PLL) applications. At the core of a PLL, the Phase Frequency Detector plays a crucial role by generating a timing output corresponding to the input phase error. During the locking process in a PLL, the reference clock and feedback clock exhibit variable phase errors. The PFD identifies these errors and generates an error signal proportional to the input phase error. This signal then drives the Voltage Control Oscillator (VCO) to adjust its frequency, reducing the phase error to zero. Conventional PFDs typically employ flip-flops to detect phase errors, resulting in more logic gates and increased jitter. In contrast, the proposed approach utilizes an edge detection strategy to minimize the number of gates, thereby reducing noise and Random Jitter (RJ).

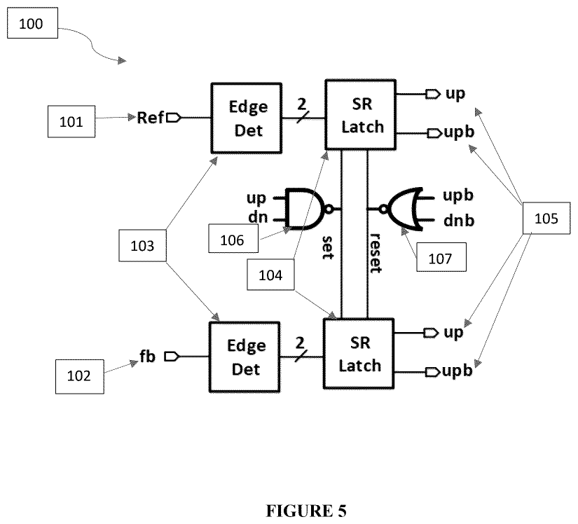

FIG. 5 illustrates a block-level implementation of the present phase frequency detector (100) comprising two edge detectors (103), two SR latches (104), one NAND gate (106), and one NOR gate (107). A reference (Ref) (101) and feedback signals (Fb) (102) are provided to the two edge detector (103) as an inputs. The edge detector (103) generates a pulse of active low logic (low-time and high for the remaining duration). The active low time depends on the inverter delay, typically in the range of 20-30 ps. The output of the edge detector (103) is provided to the two SR latches (104), which provide output signals of the proposed phase frequency detectors. The latch triggered by the clock leading in phase sets its output high, facilitating phase detection. Parallel resets for both NAND (106) and NOR gates (107) are incorporated to expedite the reset process and enhance dead zone performance. At the end, PFD generates complementary up (UP and UPb) and down (DN and DNb) signals (105) from reference (Ref) (101) and and feedback signals (Fb) (102).

The proposed PFD enhances the operating frequency while minimizing jitter. The key concept involves converting the clock into narrow-width pulses instead of transmitting the rising/falling edges. This modification broadens the frequency range of the PFD. An edge detector (103) is employed to reduce the duty cycle of the reference (Ref) (101) and feedback (Fb) clocks (102) to a minimal 10%. This adjustment enables the detection of rising and falling edges by measuring the pulse width. The pulses are subsequently applied to Set-Reset (SR) latches, triggering their output whenever a high-level pulse is detected. Notably, this proposal streamlines the automatic generation of up/dn signals, eliminating the need for additional components.

The proposed Phase Frequency Detector (PFD) introduces a streamlined design with only 3 to 4 gates in the signal path, minimizing complexity and enhancing efficiency. The avoidance of the ‘1/1’ state for up/dn is achieved by feeding them into a NAND gate (106) and upb/dnb into a NOR gate (107), controlling the Set/Reset (SR) latches.

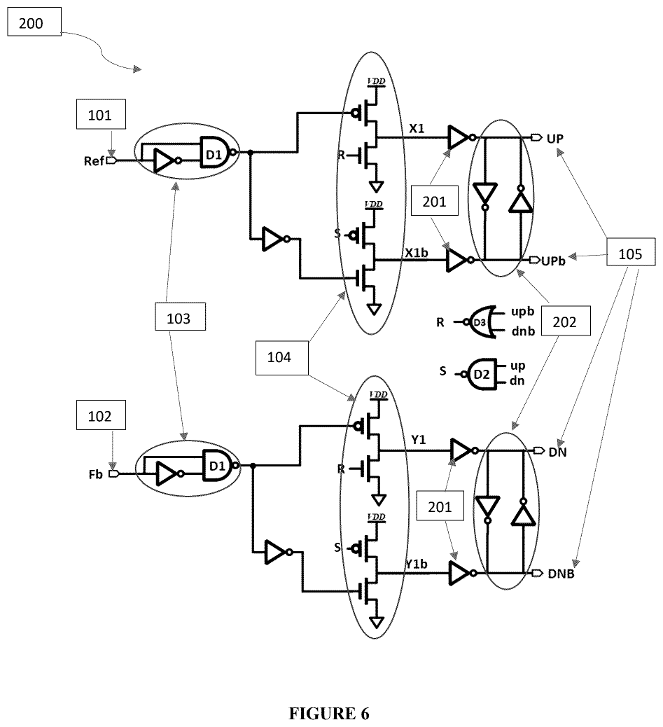

FIG. 6 illustrates a transistor-level implementation of the phase frequency detector (PFD) (200) comprising 2 edge detectors (103), 2 SR latch, one NAND gate (106), one NOR gate (107), and multiple inverters (201) (202). The edge detector (103) receives reference (Ref) (101) and feedback (Fb) clocks (102) at the inputs where Edge detector (103) circuit presents the transistor-level schematic using NAND (106)/NOR (107) gates as building blocks. The edge detector (103) is designed by ANDing the clock signal with its complementary signal, generating a pulse with active low logic (brief low-time and high for the remaining duration). The active low time depends on the inverter delay, typically in the range of 20-30 ps. These narrow pulses from the reference (Ref) (101) and feedback (Fb) clocks (102) are then applied to the SR latch (104), wherein the SR latch (104) consists of an NMOS/PMOS-based structure. The latch triggered by the clock leading in phase sets its output high, facilitating phase detection. The latch triggered by the clock leading in phase sets its output high, facilitating phase detection. Parallel resets for both NAND (106) and NOR gates (107) are incorporated to expedite the reset process and enhance dead zone performance.

The output of two SR latch (104) is buffered though two invertors (201) to ensure sufficient driving strength for subsequent stages. Additionally, a pair of cross-coupled inverters (202) is included to generate complementary up (UP and UPb) and down (DN and DNb) signals (105) from reference (Ref) (101) and feedback signals (Fb) (102) by rejecting common-mode noise. This technique inherently provides complementary (105) and down signals without additional signal generation methods. The total number of gates in the signal path ranges from 3 to 4, contingent on the previous state.

The inverters (201) shown in FIG. 6 comprises a circuit configured with an nMOS (M1) transistor current discharge, and pMOS (M2) for the current charge, wherein the gate terminal of NMOS (M1) and PMOS (M2) transistors are shorted which receive an input signal (In), and the source terminal of NMOS (M1) and drain terminal of PMOS (M2) transistors are shorted.

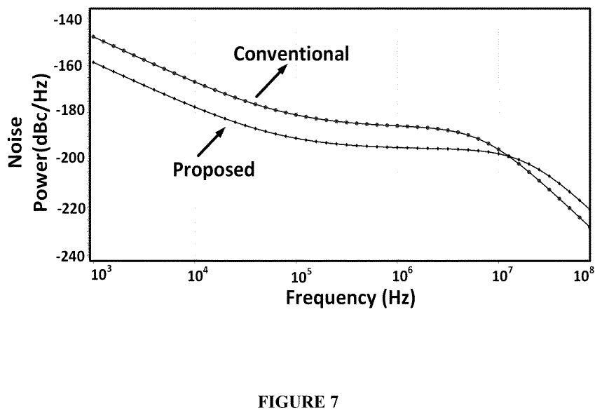

FIG. 7 illustrates graph showing a comparison of phase noise performance between the proposed PFD and the conventional PFD, both operating at 350 MHz under a 1V power supply. At 1 kHz, the proposed and conventional PFD exhibit phase noise levels of −170 dBc and −159 dBc, respectively, indicating an 11 dB improvement. While the proposed technique performs slightly worse at high frequencies, its impact on overall integrated jitter is negligible.

In some embodiments, the PFD identifies phase errors and generates an error signal proportional to the input phase error. This signal then drives the Voltage Control Oscillator (VCO) to adjust its frequency, reducing the phase error to zero.

In some embodiments, the proposed Phase Frequency Detector (PFD) circuit (200) utilizes an edge detection strategy to minimize the number of gates, thereby reducing noise and Random Jitter (RJ).

In some embodiments, the Phase Frequency Detector (PFD) circuit (200) comprises an edge detector (103) is employed to reduce the duty cycle of the reference (Ref) (101) and feedback (Fb) signal (102) to a minimal 10%.

In some embodiments, the parallel resets for both NAND (106) and NOR gates (107) are incorporated to expedite the reset process and enhance dead zone performance.

In some embodiments, the Phase Frequency Detector (PFD) introduces a streamlined design by using only 3 to 4 gates in the signal path, to minimize complexity and enhancing efficiency.

### EQUIVALENTS

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present.

Although implementations for the edge generation-based phase frequency detector (PFD) have been described in language specific to structural features and/or methods, it is to be understood that the appended claims are not necessarily limited to the specific features described. Rather, the specific features are disclosed as examples of implementation for the edge generation-based phase frequency detector (PFD).

1. A phase frequency detector (PFD), comprising:
a first edge detection circuit (103) configured to receive a reference clock signal (101) and generate a first output signal indicative of an edge of the reference clock signal;
a second edge detection circuit (103) configured to receive a feedback clock signal and generate a second output signal indicative of an edge of the feedback clock signal;
a phase detection circuit configured to receive the first and second output signals and generate a third signal indicative of a phase difference between the reference clock signal and the feedback clock signal, wherein the phase detection circuit comprises:
two SR latches, each configured to receive one of the first and second output signals;
a first logic gate configured to receive outputs of the two SR latches and generate a first output signal indicative of the phase difference; and
a second logic gate configured to receive outputs of the two SR latches and generate a second output signal complementary to the first output signal.

2. The PFD as claimed in claim 1, wherein each edge detection circuit comprises a NAND gate configured to receive the corresponding clock signal and a complement of the corresponding clock signal.

3. The PFD as claimed in claim 2, wherein the NAND gates (106) of the edge detection circuits comprise transistors.

4. The PFD as claimed in claim 3, wherein the transistors are configured as NMOS transistors.

5. The PFD as claimed in claim 1, wherein the first and second logic gates are NAND gates.

6. The PFD as claimed in claim 1, further comprising:
a first inverter (201) configured to receive the first output signal of the phase detection circuit; and
a second inverter (202) configured to receive the output of the first inverter, wherein the PFD is configured to output the first output signal of the phase detection circuit as a first up signal and the output of the second inverter as a down signal.

7. The PFD as claimed in claim 6, further comprising a reset circuit configured to reset the SR latches.

8. The PFD as claimed in claim 7, wherein the reset circuit comprises a third logic gate configured to receive the first and second output signals of the phase detection circuit and generate a reset signal.

9. The PFD as claimed in claim 8, wherein the third logic gate is a NOR gate (107).

10. The PFD as claimed in claim 1, wherein the edge detection circuits are configured to generate output signals with a pulse width of less than 50% of a period of the corresponding clock signal.

11. The PFD as claimed in claim 1, wherein the PFD operates at a frequency greater than 1 GHz.

12. A method for generating up and down signals indicative of a phase difference between a reference clock signal and a feedback clock signal, the method comprising:
generating first and second output signals indicative of edges of the reference clock signal and the feedback clock signal, respectively;
receiving the first and second output signals in a phase detection circuit;
generating a first output signal indicative of the phase difference based on the first and second output signals; and
generating a second output signal complementary to the first output signal.
